(19) United States
(12) Patent Application Publication
(10) Pub. No.: US 2024/0322105 A1
(43) Pub. Date: Sep. 26, 2024

(54) DISPLAY PANEL, SPLICING SCREEN, AND DISPLAY APPARATUS

(71) Applicant: Tianma Advanced Display Technology Institute (Xiamen) Co.,Ltd., Xiamen (CN)

(72) Inventors: Xuhui PENG, Xiamen (CN); Zhenyu JIA, Xiamen (CN); Qinyi DUAN, Xiamen (CN); Kerui XI, Xiamen (CN); Tianyi WU, Xiamen (CN); Xiaoxiang HE, Xiamen (CN); Yingru HU, Xiamen (CN); Yingteng ZHAI, Xiamen (CN); Yukun HUANG, Xiamen (CN); Aowen LI, Xiamen (CN)

(21) Appl. No.: 18/736,511

(22) Filed: Jun. 6, 2024

(30) Foreign Application Priority Data
Dec. 29, 2023 (CN) 202311871415.1

(51) Int. Cl. H01L 33/62; H01L 25/075; H01L 25/16; H01L 27/12

(52) U.S. Cl. CPC H01L 33/62; H01L 25/0753; H01L 25/167; H01L 27/124

(57) ABSTRACT

A display panel, a splicing screen, and a display apparatus. The display panel comprises an array base plate comprising a substrate as well as a plurality of transistors and a plurality of connection electrodes located on one side of the substrate; the plurality of transistors comprise a first transistor, and the plurality of connection electrodes comprise a first connection electrode; the array base plate has at least one first edge; the first transistor is adjacent to the first edge, and the first connection electrode is adjacent to the first edge, a distance between the first transistor and the first edge is greater than a distance between the first connection electrode and the first edge. The present invention can reduce the risk of failure of the transistors near the cutting edge due to laser cutting in the laser cutting process, and can improve the production yield of narrow-bezel or bezel-free products.

### CROSS-REFERENCE TO RELATED APPLICATIONS

The present application claims priority to Chinese Patent Application No. 202311871415.1, filed on Dec. 29, 2023, the content of which is incorporated herein by reference in its entirety.

### TECHNICAL FIELD

The present invention relates to the field of display technologies, and in particular, to a display panel, a splicing screen, and a display apparatus.

### BACKGROUND

Currently, there is a growing demand for large-screen displays in many fields, such as public information presentation, billboards, and large-screen displays in meeting rooms. The technology of splicing a plurality of small-sized screens with each other to form a large-sized splicing screen has emerged accordingly. Currently, liquid crystal displays, mini light-emitting diodes (Mini LEDs), micro LEDs, etc. can be applied to make a splicing display screen. However, a technical problem of low production yield of display panels exists in narrow-bezel or even bezel-free products.

### SUMMARY

The examples of the present invention provide a display panel, a splicing screen, and a display apparatus, to improve production yield.

In a first aspect, an example of the present invention provides a display panel comprising an array base plate, wherein the array base plate comprises a substrate as well as a plurality of transistors and a plurality of connection electrodes located on one side of the substrate;
the plurality of transistors comprise a first transistor, the plurality of connection electrodes comprise a first connection electrode, and the array base plate has at least one first edge;
the first transistor is adjacent to the first edge, the first connection electrode is adjacent to the first edge, and a distance between the first transistor and the first edge is greater than a distance between the first connection electrode and the first edge.

In a second aspect, based on the same inventive concept, an example of the present invention further provides a splicing screen comprising at least two display panels provided by any example of the present invention.

In a third aspect, based on the same inventive concept, an example of the present invention further provides a display apparatus comprising a display panel provided by any example of the present invention.

The display panel, splicing screen, and display apparatus provided by the examples of the present invention have the following beneficial effects: the connection electrodes in the display panel provided by the examples of the present invention are used to bind light-emitting devices, the first connection electrode is adjacent to the first edge, and by setting the first transistor further away from the first edge compared to the first connection electrode, the distance between the transistor adjacent to the first edge and the first edge can be increased. The examples of the present invention can reduce the risk of failure of the transistors near the cutting edge due to laser cutting in the laser cutting process, and can improve the production yield of narrow-bezel or bezel-free products.

### BRIEF DESCRIPTION OF DRAWINGS

To explain the technical solutions in the examples of the present invention or in the prior art more clearly, the following briefly describes the accompanying drawings required for describing the examples or the prior art. Apparently, the accompanying drawings in the following description show some examples of the present invention, and those skilled in the art may also derive other drawings from these accompanying drawings without creative efforts.

FIG. 1 is a schematic diagram of a display panel provided by an example of the present invention;

FIG. 2 is a schematic diagram of another display panel provided by an example of the present invention;

FIG. 3 is a schematic diagram of another display panel provided by an example of the present invention;

FIG. 4 is a schematic cross-sectional view taken along a section line A-A′ in FIG. 2;

FIG. 5 is a schematic diagram of another display panel provided by an example of the present invention;

FIG. 6 is a schematic diagram of another display panel provided by an example of the present invention;

FIG. 7 is a schematic diagram of another display panel provided by an example of the present invention;

FIG. 8 is a schematic diagram of another display panel provided by an example of the present invention;

FIG. 9 is a schematic diagram of another display panel provided by an example of the present invention;

FIG. 10 is a schematic diagram of another display panel provided by an example of the present invention;

FIG. 11 is a schematic diagram of another display panel provided by an example of the present invention;

FIG. 12 is a schematic diagram of another display panel provided by an example of the present invention;

FIG. 13 is a schematic diagram of another display panel provided by an example of

the present invention;

FIG. 14 is a schematic diagram of another display panel provided by an example of the present invention; and

FIG. 15 is a schematic diagram of a splicing screen provided by an example of the present invention.

### DESCRIPTION OF EMBODIMENTS

To make the objectives, technical solutions, and advantages of the examples of the present invention clearer, the technical solutions in the examples of the present invention will be clearly and completely described below with reference to the accompanying drawings in the examples of the present invention. Apparently, the described examples are some rather than all of the examples of the present invention. All other examples obtained by those ordinarily skilled in the art based on the examples of the present invention without creative efforts should fall within the protection scope of the present invention.

Terms used in the examples of the present invention are only for the purpose of describing specific examples, and are not intended to limit the present invention. Unless otherwise indicated clearly in the context, words, such as “a”, “the”, and “this”, in a singular form in the examples of the present invention and the appended claims comprise plural forms.

It should be understood that although the terms “first” and “second” may be used to describe XX in the examples of the present invention, these XXs should not be limited by these terms. These terms are merely used to distinguish the XXs from one other. For example, a first XX can also be referred to as a second XX without departing from the scope of the examples of the present invention. Similarly, a second XX can also be referred to as a first XX.

In the fabrication of a narrow-bezel or bezel-free display panel, the edges of the display panel will be cut by using a laser cutting process. The thin-film transistors in a narrow-bezel or bezel-free product are close to the cutting edges, which leads to a greater risk of failure of the thin-film transistors caused by the laser cutting process, which results in a problem with the yield of the product.

To address the technical problem existing in the related art, the examples of the present invention provide a display panel comprising an array base plate and light-emitting devices located on one side of the array base plate. The light-emitting devices may be light-emitting diodes (LEDs), such as Mini LEDs or Micro LEDs. Connection electrodes are provided on the array base plate, and the light-emitting devices are bound and connected to the array base plate via the connection electrodes. The transistors in the array base plate adjacent to a cutting edge are provided to be inwardly retracted so that the transistors are away from the cutting edge, thereby avoiding the damage caused by the laser cutting process to the transistors at the edge position. On at least a part of edge position on the array base plate, a transistor in a pixel circuit is adjacent to the edge, and on at least a part of edge position on the array base plate, a transistor in a shift drive circuit is adjacent to the edge. In some embodiments, a connection electrode adjacent to the edge is closer to the edge than the transistor adjacent to the edge. In other words, a distance between the connecting electrode closest to the edge and the edge is less than a distance between the transistor closest to the same edge and the edge. Wherein, the transistor adjacent to the edge may belong to either the pixel circuit or the shift drive circuit. In some embodiments, the pixel circuit is shifted towards the inside of the display panel, so that the shift drive circuit adjacent to the pixel circuit can also be shifted in a direction away from the edge, which means that the distance between the transistor in the shift drive circuit that is adjacent to the edge and the edge become big, whereby it is possible to reduce the influence of the laser cutting process on the transistor. Some examples of the present invention also involve solutions of how the pixel circuit is connected to the connection electrode when the pixel circuit is provided away from the edge, and solutions of how the pixel circuit and the shift drive circuit, etc. are arranged, and the like. The above is an overview of the technical concept of the present invention, and the technical concept of the present invention will be explained in detail below with specific examples.

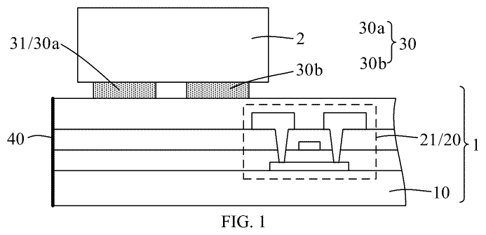

An example of the present invention provides a display panel. FIG. 1 is a schematic diagram of a display panel provided by the example of the present invention. As shown in FIG. 1, the display panel comprises an array base plate 1, which comprises a substrate 10 as well as a plurality of transistors 20 and a plurality of connection electrodes 30 located on one side of the substrate 10. A light-emitting device 2 is also provided on the array base plate 1 and bound and connected to the array base plate 1 via the connection electrodes 30, wherein the connection electrodes 30 comprise a first electrode 30a and a second electrode 30b, one of which is connected to an anode of the light-emitting device 2 and the other is connected to a cathode of the light-emitting device 2. The plurality of transistors 20 comprise a first transistor 21, and the plurality of connection electrodes 30 comprise a first connection electrode 31. The array base plate 1 has at least one first edge 40; in a direction perpendicular to the first edge 40, the first transistor 21 is adjacent to the first edge 40, and the first connection electrode 31 is adjacent to the first edge 40. It can be seen from FIG. 1 that a distance between the first transistor 21 and the first edge 40 is greater than a distance between the first connection electrode 31 and the first edge 40. Wherein, the first edge 40 is an edge formed after cutting along a cutting path using a laser cutting process during manufacture. In some embodiments, the distance between the transistor and the first edge 40 is calculated based on a distance between a channel of the transistor and the first edge 40.

In some embodiments, “the first transistor 21 adjacent to the first edge 40” is understood as the first transistor 21 being closest to the first edge 40 compared to other transistors (without limiting the circuit structure to which the transistors belong). In other words, there is no other transistor between the first transistor 21 and the first edge 40. By setting the first transistor 21 further away from the first edge 40 compared to the first connection electrode 31, it is possible to reduce the influence of the laser cutting process on the first transistor 21.

In some embodiments, “the first transistor 21 adjacent to the first edge 40” is understood as the first transistor 21 being closest to the first edge 40 compared to other transistors in the circuit structure in which the first transistor 21 is located. In some examples, the first transistor 21 belongs to a pixel circuit. The first transistor 21 is the transistor in the pixel circuit that is closest to the first edge 40, and the first transistor 21 is further away from the first edge 40 compared to the first connection electrode 31, which can reduce the influence of the laser cutting process on the first transistor 21. When a shift drive circuit is further provided between the pixel circuit and the first edge 40, and the pixel circuit in which the first transistor 21 is located is coupled to the first connection electrode 31 such that the pixel circuit and the connection electrode 30 coupled thereto are provided in a staggered manner, the pixel circuit is shifted towards the inside of the display panel, and thus the shift drive circuit is also adaptively shifted in the layout position in a direction away from the first edge 40, which can reduce the influence of the laser cutting process on the transistor in the shift drive circuit. In other examples, the first transistor 21 belongs to the shift drive circuit, is the transistor in the shift drive circuit that is closest to the first edge 40, and is further away from the first edge 40 compared to the first connection electrode 31, which can reduce the influence of the laser cutting process on the transistor in the shift drive circuit. In other examples, the first transistor 21 belongs to an electrostatic discharge (ESD) protection circuit and is the transistor in the ESD protection circuit that is closest to the first edge 40, which can reduce the influence of the laser cutting process on the transistor in the ESD protection circuit.

In some embodiments, “the first transistor 21 adjacent to the first edge 40” is understood as the first transistor 21 being closest to the first edge 40 compared to other transistors in the circuit structure in which the first transistor 21 is located. In some examples, the first transistor 21 may be closer to the first edge than first transistors of the same kind or function in other pixel circuits. Wherein, “the first transistor 21 adjacent to the first edge 40” is located in “the pixel circuit adjacent to the first edge 40”. Here, a comparison is made between two transistors from different pixel circuits, such as drive transistors from two pixel circuits.

In the display panel provided by the examples of the present invention, the connection electrodes 30 are used to bind the light-emitting device, the first connection electrode 31 is adjacent to the first edge 40, and by setting the first transistor 21 further away from the first edge 40 compared to the first connection electrode 31, it is possible to increase the distance between the transistor adjacent to the first edge 40 and the first edge 40. In the process of forming the first edge 40 by laser cutting, it is possible to reduce the risk of failure of the transistors near the cutting edge due to laser cutting, being capable of improving the production yield of narrow-bezel or bezel-free products.

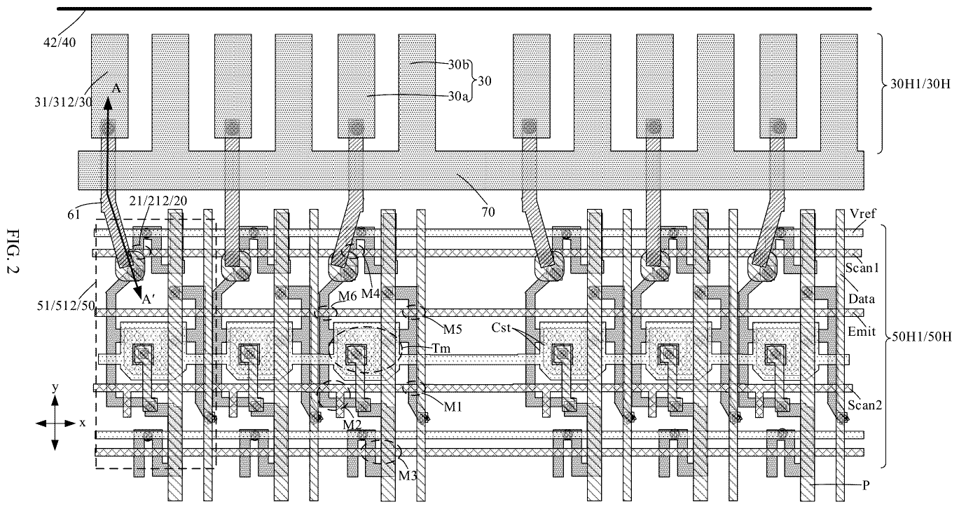

In some embodiments, in the circuit structure in which the first transistor 21 is located, the first transistor 21 is closest to the first edge 40 compared to other transistors. The first transistor 21 belongs to a pixel circuit, and the first connection electrode 31 is coupled to the pixel circuit in which the first transistor 21 is located. FIG. 2 is a schematic diagram of another display panel provided by an example of the present invention. As shown in FIG. 2, pixel circuits 50 in the array base plate comprise a first pixel circuit 51, which comprises a first transistor 21. A first connection electrode 31 is adjacent to the first edge 40. The first pixel circuit 51 is coupled to the first connection electrode 31. It can be seen from FIG. 2 that the distance between the first transistor 21 and the first edge 40 is greater than the first connection electrode 31, indicating that the first pixel circuit 51 and the first connection electrode 31 connected thereto are staggered in the direction perpendicular to the first edge 40. In FIG. 2, the first pixel circuit 51 is schematically illustrated adjacent to the first edge 40, and the first transistor 21 is further away from the first edge 40 compared to the first connection electrode 31, which can reduce the influence of the laser cutting process on the first transistor 21, improving product yield.

In other embodiments, the first transistor 21 belongs to the first pixel circuit 51, and the shift drive circuit is further provided between the first pixel circuit 51 and the first edge 40, that is, the shift drive circuit is adjacent to the first edge 40. Since the first pixel circuit 51 and the first connection electrode 31 connected thereto are staggered, so that the first pixel circuit 51 is shifted in the direction away from the first edge 40, whereby the shift drive circuit can also be adaptively shifted in the layout position in the direction away from the first edge 40, which can reduce the influence of the laser cutting process on the transistor in the shift drive circuit. This embodiment will be illustrated in the related embodiments below with reference to the accompanying drawings.

The pixel circuit 50 shown in FIG. 2 comprises a drive transistor Tm, a data writing transistor M1, a threshold compensation transistor M2, a gate reset transistor M3, an electrode reset transistor M4, a first light emission control transistor M5, a second light emission control transistor M6, and a storage capacitor Cst. A first scan line Scan1, a second scan line Scan2, a reset line Vref, a light emission control line Emit, a data line Data, and a power line P are further provided in the array base plate. A gate of the gate reset transistor M3 and a gate of the electrode reset transistor M4 are electrically connected to the first scan line Scan1. A gate of the data writing transistor M1 and a gate of the threshold compensation transistor M2 are electrically connected to the second scan line Scan2. A gate of the first light emission control transistor M5 and a gate of the second light emission control transistor M6 are electrically connected to the light emission control line Emit. The data line Data is used to provide a data signal to the pixel circuit 50, and the power line P is used to provide a constant voltage signal to the pixel circuit 50. The pixel circuit 50 in FIG. 2 is for illustration only and is not intended to limit the present invention.

FIG. 2 illustrates that the connection electrodes 30 comprise a first electrode 30a and a second electrode 30b. The pixel circuit 50 is coupled to the first electrode 30a, and a plurality of second electrodes 30b are electrically connected to a common electrode line 70.

As shown in FIG. 2, the display panel further comprises a first bridging line 61. The first pixel circuit 51 is coupled to the first connection electrode 31 through the first bridging line 61. When the first pixel circuit 51 and a first connection electrode 31 corresponding thereto are staggered, an electrical connection is established between the two by setting the first bridging line 61.

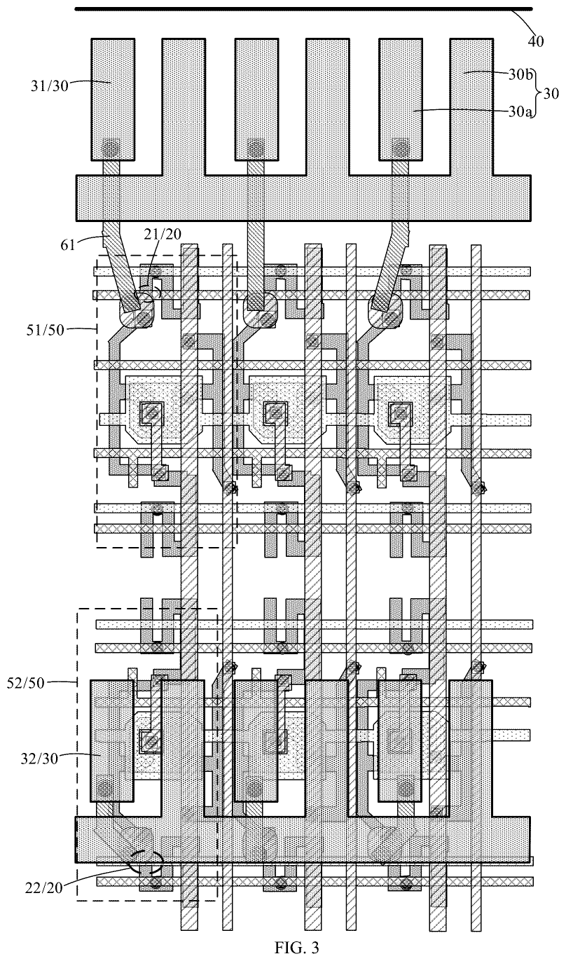

In some embodiments, FIG. 3 is a schematic diagram of another display panel provided by an example of the present invention. As shown in FIG. 3, the plurality of transistors 20 further comprise a second transistor 22, and the plurality of connection electrodes 30 further comprise a second connection electrode 32. The pixel circuits 50 further comprise a second pixel circuit 52, which comprises the second transistor 22 and is coupled to the second connection electrode 32. The second transistor 22 in the second pixel circuit 52 is similar to the first transistor 21 in the first pixel circuit 51 in function. It can be seen from FIG. 3 that, in the direction perpendicular to the first edge 40, a distance between the first transistor 21 and the first connection electrode 31 is greater than a distance between the second transistor 22 and the second connection electrode 32. In FIG. 3, it is illustrated that the second connection electrode 32 overlaps the second pixel circuit 52, and the second connection electrode 32 is substantially not staggered from the second pixel circuit 52. In this embodiment, the first pixel circuit 51 is the pixel circuit closest to the first edge 40 among the pixel circuits 50. By setting the first pixel circuit 51 and the first connection electrode 31 connected thereto to be staggered, it is possible to enable a distance between the transistor adjacent to the first edge 40 and the first edge 40 to be increased, thereby reducing the influence of the laser cutting process on the transistor 20 at the edge position and improving product yield.

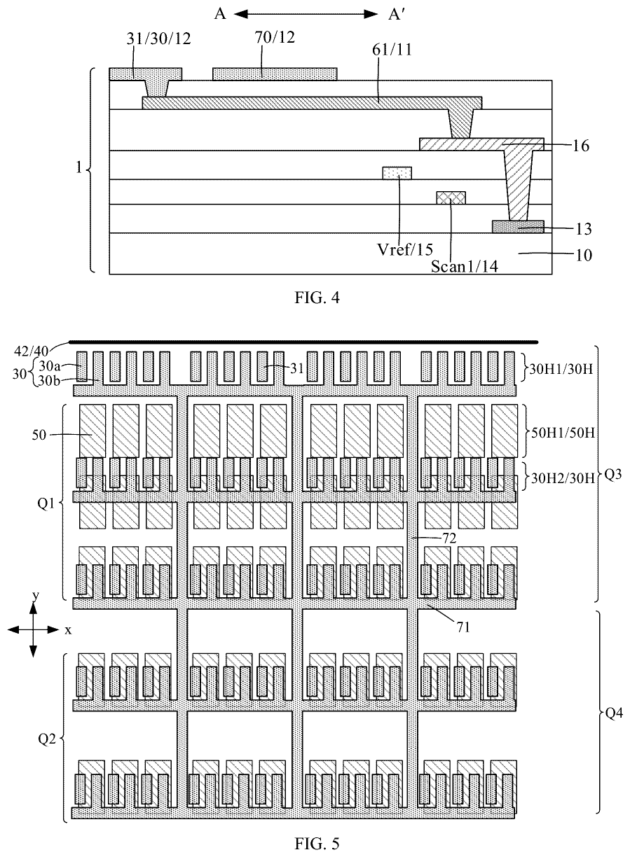

In some embodiments, FIG. 4 is a schematic cross-sectional view taken along a section line A-A′ in FIG. 2. As shown in FIG. 4, the array base plate 1 comprises a first metal layer 11 and a second metal layer 12. The second metal layer 12 is located on a side of the first metal layer 11 away from the substrate 10. The first bridging line 61 is located in the first metal layer 11, and the plurality of connection electrodes 30 are located in the second metal layer 12. As shown in FIG. 4, the array base plate 1 further comprises a semiconductor layer 13, a third metal layer 14, a fourth metal layer 15, and a fifth metal layer 16 that are provided sequentially away from the substrate 10. Wherein, active layers of the plurality of transistors 20 are located in the semiconductor layer 13. The first scan line Scan1, the second scan line Scan2, and the light emission control line Emit are located within the third metal layer 14. The reset line Vref is located in the fourth metal layer 15. One plate of the storage capacitor Cst is located in the third metal layer 14, and the other plate is located in the fourth metal layer 15. Optionally, the data line Data and the power line P are located in the fifth metal layer 16.

In other embodiments, a sixth metal layer is provided between the fifth metal layer 16 and the first metal layer 11. One of the data line Data and the power line P is located in the fifth metal layer, and the other is located in the sixth metal layer, or at least one of the data line Data and the power line P is set as a dual-layer routing. Taking the case where the data line Data is a dual-layer routing for example, that is, data sub-lines are provided in both the fifth metal layer and the sixth metal layer, and the data sub-lines located in the two layers are connected in parallel to form the data line Data.

In some embodiments, FIG. 5 is a schematic diagram of another display panel provided by an example of the present invention. As shown in FIG. 5, a layout area of the pixel circuits 50 in the display panel comprises a first region Q1 and a second region Q2, and the first region Q1 is located on a side of the second region Q2 close to the first edge 40. A layout density of the pixel circuits 50 in the first region Q1 is greater than a layout density of the pixel circuits 50 in the second region Q2. The structure of the pixel circuit 50 in FIG. 5 is simplified for illustrative purposes. By differentially setting the layout densities of the pixel circuits 50 in different regions, so that the layout density of the pixel circuits 50 at the position close to the first edge 40 is greater, and thus the pixel circuits 50 close to the first edge 40 are inwardly retracted, such that the distance between the transistors in the pixel circuits 50 and the first edge 40 is increased. When the pixel circuits 50 are adjacent to the first edge 40, setting the transistors within the pixel circuits 50 near the first edge 40 at an increased distance from the first edge 40 can reduce the influence of the laser cutting process on the transistors in the pixel circuits 50, improving product yield. When a shift drive circuit is further provided between the pixel circuits 50 and the first edge 40, by setting the pixel circuits 50 close to the first edge 40 inwardly retracted, the shift drive circuit can also be adaptively shifted in the layout position in the direction away from the first edge 40 to be inwardly retracted, and thus it is possible to reduce the influence of the laser cutting process on the transistors in the shift drive circuits and improve the product yield.

As shown in FIG. 5, first common electrode lines 71 and second common electrode lines 72 are further provided in the array base plate. The first common electrode lines 71 extend along a row direction x, and the second common electrode lines 72 extend along a column direction y. One first common electrode line 71 connects a plurality of second electrodes 30b. The first common electrode lines 71 and the second common electrode lines 72 intersect each other and are electrically connected to form a mesh-like wiring. In this way, it is possible to reduce the voltage drop of the common electrode lines and improve the uniformity of in-plane signals.

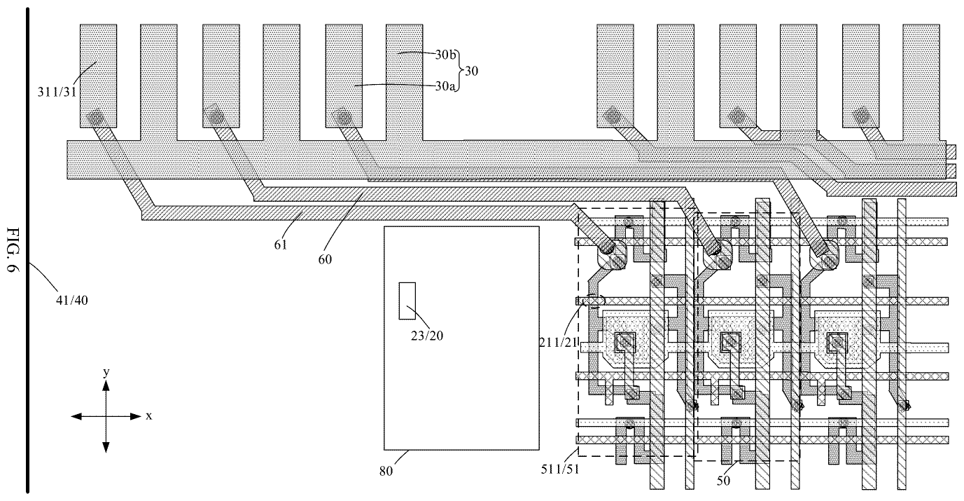

In other embodiments, the first edge 40 comprises a first sub-edge, and the shift drive circuit is provided between the first sub-edge and the pixel circuit 50. FIG. 6 is a schematic diagram of another display panel provided by an example of the present invention. As shown in FIG. 6, the first edge 40 comprises a first sub-edge 41 extending along the column direction y, the first transistor 21 comprises a first sub-transistor 211, and the first connection electrode 31 comprises a first connection sub-electrode 311. Along the row direction x, the first sub-transistor 211 is adjacent to the first sub-edge 41, the first connection sub-electrode 311 is adjacent to the first sub-edge 41, and a distance between the first sub-transistor 211 and the first sub-edge 41 is greater than a distance between the first connection sub-electrode 311 and the first sub-edge 41. The row direction x and the column direction y are perpendicular to each other. The first pixel circuit 51 comprises a first pixel sub-circuit 511, which comprises a first sub-transistor 311 and is coupled to the first connection sub-electrode 311 via a first bridging line 61. When the pixel circuit 50 and the connection electrode 30 corresponding thereto are staggered in the display panel shown in FIG. 6, the pixel circuit 50 and the connection electrode 30 are electrically connected through a bridging line 60. In this embodiment, the first connection sub-electrode 311 is adjacent to the first sub-edge 41, and the first pixel sub-circuit 511 and the first connection sub-electrode 311 connected thereto are staggered, so that the first pixel sub-circuit 511 is shifted in a direction away from the first sub-edge 41 relative to the first connection sub-electrode 311. In this way, it is possible to reserve more wiring space between the first pixel sub-circuit 511 and the first sub-edge 41.

As shown in FIG. 6, the display panel further comprises a shift drive circuit 80; the shift drive circuit 80 is located on a side of the plurality of pixel circuits 50 close to the first sub-edge 41. That is, in the row direction x, the shift drive circuit 80 is adjacent to the first sub-edge 41. The plurality of transistors 20 further comprise a third transistor 23, and the shift drive circuit 80 comprises the third transistor 23. The third transistor 23 is a transistor in the shift drive circuit 80 that is closest to the first sub-edge 41. Along the row direction x, a distance between the third transistor 23 and the first sub-edge 41 is greater than a distance between the first connection electrode 31 and the first sub-edge 41. When the first pixel circuit 51 and the first connection electrode 31 connected thereto are staggered in the example shown in FIG. 6, the first pixel circuit 51 is shifted in a direction away from the first sub-edge 41 relative to the first connection electrode 31. In this way, the shift drive circuit 80 can also be adaptively shifted in the layout position in the direction away from the first sub-edge 41 to be inwardly retracted, such that the distance between the third transistor 23 and the first sub-edge 41 is increased, whereby it is possible to reduce the influence of the laser cutting process on the third transistor 23 and improve product yield.

The shift drive circuit 80 in FIG. 6 is shown in a simplified schematic only, and the shift drive circuit 80 comprises a plurality of shift registers in cascade. The shift register can be any circuit structure capable of realizing the signal shifting function in the prior art.

The shift drive circuit 80 in the display panel comprises a scan drive circuit and a light emission drive circuit. The scan drive circuit and the light emission drive circuit each comprise a plurality of shift registers in cascade. Wherein, the first scan line Scan1 and the second scan line Scan2 in the display panel are coupled to the scan drive circuit, and the light emission control line Emit is coupled to the light emission drive circuit. The scan lines and the light emission control lines in the display panel extend along the row direction x, and the data lines extend along the column direction y.

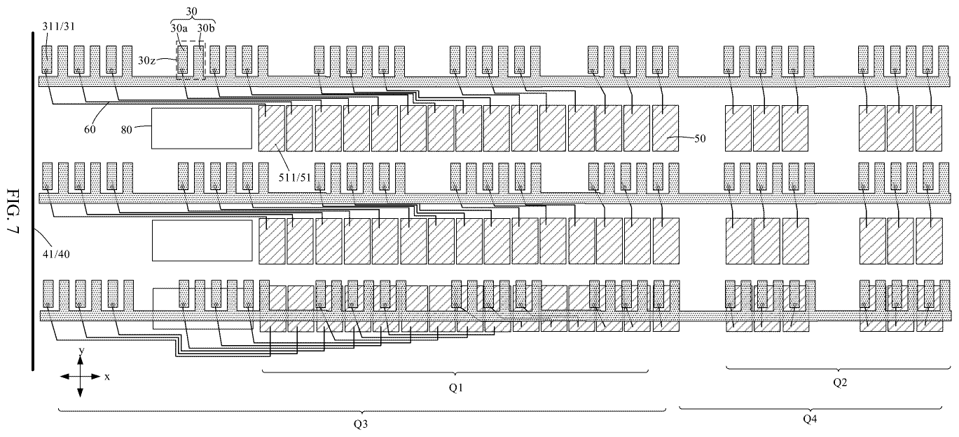

In other embodiments, FIG. 7 is a schematic diagram of another display panel provided by an example of the present invention. As shown in FIG. 7, a first electrode 30a and a second electrode 30b form an electrode group 30z. The pixel circuit 50 is coupled to the first electrode 30a in the electrode group 30z, and in FIG. 7, the structure of the pixel circuit 50 is shown in a simplified schematic only. The first edge 40 comprises a first sub-edge 41 extending along the column direction y. The first connection sub-electrode 311 is adjacent to the first sub-edge 41 and coupled to the first pixel sub-circuit 511. The first pixel sub-circuit 511 the one of the pixel circuit 50 that is closest in distance to the first sub-edge 41. A layout area of the pixel circuits 50 comprises a first region Q1. The pixel circuit 50 in the first region Q1 and the electrode group 30z connected thereto are staggered in the row direction x, and the first pixel sub-circuit 511 is located in the first region Q1. The shift drive circuit 80 is located between the first region Q1 and the first sub-edge 41. In the row direction x, the pixel circuit 50 close to the first sub-edge 41 and the electrode group 30z corresponding thereto are staggered. That is, a part of the pixel circuit 50 is provided in the first region Q1 and shifted in the direction away from the first sub-edge 41, such that the shift drive circuit 80 can also be adaptively shifted in the layout position in the direction away from the first sub-edge 41 to be inwardly retracted, thereby reducing the influence of the laser cutting process on the transistor in the shift drive circuit 80 and improving the product yield.

As shown in FIG. 7, the first region Q1 is a region where the pixel circuits 50 are densely packed. Densely packing a plurality of pixel circuits 50 in the row direction x in the first region Q1 can saving space in the row direction x, such that the shift drive circuit 80 is shifted inward by a greater distance, whereby increasing the distance between the transistors and the first sub-edge 41. The layout area of the pixel circuits further comprises a second region Q2, which is located on a side of the first region Q1 away from the first sub-edge 41. In the second region Q2, the pixel circuits 50 and the electrode groups 30z connected thereto are substantially not staggered in the row direction x. The layout density of the pixel circuits 50 in the second region Q2 is lower than that of the pixel circuits 50 in the first region Q1.

In other embodiments, the first edge 40 comprises a second sub-edge, and the pixel circuit 50 is adjacent to the second sub-edge. As shown in FIG. 2, the first edge 40 comprises a second sub-edge 42 extending along the row direction x, the first transistor 21 comprises a second sub-transistor 212, and the first connection electrode 31 comprises a second connection sub-electrode 312. Along the column direction y, the second sub-transistor 212 is adjacent to the second sub-edge 42, the second connection sub-electrode 312 is adjacent to the second sub-edge 42, and a distance between the second sub-transistor 212 and the second sub-edge 42 is greater than a distance between the second connection sub-electrode 312 and the second sub-edge 42. The first pixel circuit 51 comprises a second pixel sub-circuit 512, which comprises a second sub-transistor 212 and is coupled to the second connection sub-electrode 312. The second sub-transistor 212 is the one in the second pixel sub-circuit 512 that is closest to the second sub-edge 42. Along the column direction y, the second pixel sub-circuit 512 is adjacent to the second sub-edge 42. By staggering the second pixel sub-circuit 512 and the second connection sub-electrode 312, it is possible to make the second pixel sub-circuit 512 away from the second sub-edge 42 in the column direction y, and it is possible to reduce the influence of the laser cutting process on the second sub-transistor 212 and improve the product yield.

Further referring to FIG. 2, the plurality of pixel circuits 50 are provided along the row direction x to form pixel circuit rows 50H. The pixel circuit rows 50H comprise a first pixel circuit row 50H1. The first pixel circuit row 50H1 comprises the second pixel sub-circuit 512. The first pixel circuit row 50H1 is a pixel circuit row closest to the second sub-edge 42. The plurality of connection electrodes 30 are provided along the row direction x to form electrode rows 30H. The electrode rows 30H comprise a first electrode row 30H1. The first electrode row 30H1 comprises a second connection sub-electrode 312. The first electrode row 30H1 is an electrode row closest to the second sub-edge 42. Along the column direction y, the first pixel circuit row 50H1 is located on a side of the first electrode row 30H1 away from the second sub-edge 42. This embodiment is such that the first pixel circuit row 50H1 is further away from the second sub-edge 42, which can reduce the influence of the laser cutting process on the transistors in the first pixel circuit row 50H1.

In some embodiments, as shown in FIG. 5, the first pixel circuit row 50H1 is a pixel circuit row closest to the second sub-edge 42 in the column direction y. The electrode rows 30H comprise a second electrode row 30H2 located on a side of the first electrode row 30H1 away from the second sub-edge 42. The second electrode row 30H2 is adjacent to the first electrode row 30H1. The first pixel circuit row 50H1 is located between the first electrode row 30H1 and the second electrode row 30H2. The larger the distance between the first pixel circuit row 50H1 and the second sub-edge 42, the safer the transistors in the first pixel circuit row 50H1 during the laser cutting process. However, correspondingly, the larger the distance between the first pixel circuit row 50H1 and the second sub-edge 42 and the larger the inward shift distance of the pixel circuit row 50H along the column direction y, the greater the number of the pixel circuit rows 50H that need to be changed in the layout position. In the example of the present invention, by providing the first pixel circuit row 50H1 between the first electrode row 30H1 and the second electrode row 30H2, it is possible to satisfy the safety of the transistors near the second sub-edge 42 during the laser cutting process, and at the same time it is also possible to contribute to the reduction of the number of the pixel circuit rows 50H that need to be changed in the layout position, and simplify the wiring in the array base plate.

Additionally, in the example of the present invention, the connection electrodes 30 are used to bind light-emitting devices. Each electrode row 30H correspondingly bind a plurality of light-emitting devices, and the spacing between two adjacent electrode rows 30H affects an overall pixel density of the display panel. The shift positions of the pixel circuit rows 50H near the second sub-edge 42 and the number of the pixel circuit rows that need to be shifted can be set based on the pixel density design requirements of the display panel.

In some embodiments, FIG. 8 is a schematic diagram of another display panel provided by an example of the present invention. As shown in FIG. 8, the plurality of pixel circuits 50 are provided along the row direction x to form pixel circuit rows 50H. The pixel circuit rows 50H comprise a plurality of regular pixel circuit rows 50Hs and at least one inverted pixel circuit row 50Hd. The structure of the pixel circuits 50 in the inverted pixel circuit row 50Hd is symmetrical to the structure of the pixel circuits 50 in the regular pixel circuit row 50Hs with respect to a first axis Z, which extends along the row direction x. In other words, the structure of the pixel circuits 50 in the inverted pixel circuit row 50Hd is symmetrical to the structure of the pixel circuits 50 in the regular pixel circuit row 50Hs with respect to the first axis Z. Wherein, the at least one inverted pixel circuit row 50Hd comprises the second pixel sub-circuit 512. As shown in FIG. 8, there is a significant staggered distance between the inverted pixel circuit row 50Hd and the electrode row corresponding thereto (consisting of a plurality of connection electrodes 30 provided along the row direction x, and not labeled in FIG. 8) in the column direction y, while the regular pixel circuit row 50Hs and the electrode row corresponding thereto are little or substantially not staggered in the column direction y. The provision of the inverted pixel circuit row 50Hd can reduce the distance between a signal output terminal DD of the pixel circuit 50 and the connection electrode 30 connected thereto, thereby reducing the wiring length of the bridging line 60 between the signal output terminal DD and the connection electrode 30, avoiding winding, saving wiring space, and reducing the voltage drop on the bridging line 60.

The at least one inverted pixel circuit row 50Hd comprises the second pixel sub-circuit 512. That is, at least the first pixel circuit row 50H1 closest to the second sub-edge 42 is an inverted pixel circuit row 50Hd. In practice, the number of inverted pixel circuit rows 50Hd in the display panel is set according to the distance between the first pixel circuit row 50H1 and the second sub-edge 42 as well as the pixel density design requirements of the display panel. For example, two or more inverted pixel circuit rows 50Hd can be continuously provided.

For example, in the example shown in FIG. 7, along the column direction y, the first and second pixel circuit rows counting from the top are inverted pixel circuit rows 50Hd, and the third pixel circuit row is a regular pixel circuit row 50Hs.

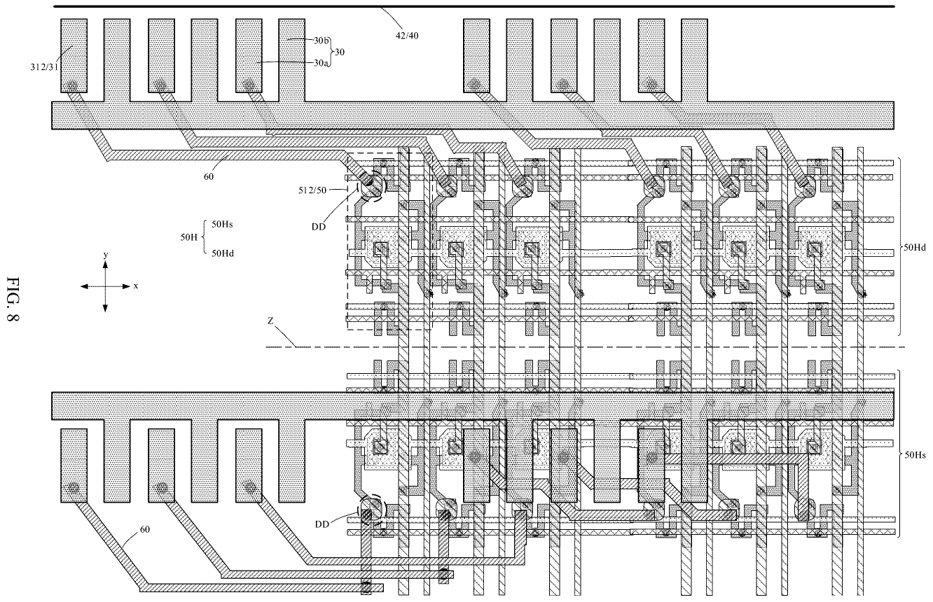

In some embodiments, FIG. 9 is a schematic diagram of another display panel provided by an example of the present invention. As shown in FIG. 9, the plurality of connection electrodes 30 are provided along the row direction x to form electrode rows 30H. The electrode rows 30H comprise a first electrode row 30H1, which comprises a second connection sub-electrode 312. That is, the first electrode row 30H1 is adjacent to the second sub-edge 42. The display panel further comprises at least one first signal line X1 extending along the row direction x. From the top view in FIG. 9, it can be seen that along a direction perpendicular to a plane of the substrate, the first electrode row 30H1 overlaps the first signal line X1. The number of first signal lines X1 in FIG. 9 is illustrative and not intended to limit the present invention. The first signal line X1 can be a signal line used to transmit a constant voltage signal, or the first signal line X1 can be an electrostatic protection line provided on the periphery of the circuit. In this embodiment, the pixel circuits 50 adjacent to the second sub-edge 42 are shifted in the direction away from the first sub-edge 42 to be inwardly retracted, such that the first signal line X1 can be arranged in such a way that it is adapted with the pixel circuits 50 and they overlap the first electrode row 30H1. In this way, no signal line can be provided between the first electrode row 30H1 and the second sub-edge 42, which is conducive to reducing the bezel of the display panel.

FIG. 9 also illustrates a first sub-edge 41 extending along the column direction y. The first connection sub-electrode 311 is adjacent to the first sub-edge 41 and is coupled to the first pixel sub-circuit 511. The first pixel sub-circuit 511 is a pixel circuit closest to the first sub-edge 41. The shift drive circuit 80 is further provided between the first pixel sub-circuit 511 and the first sub-edge 41. The signal line for driving the shift drive circuit 80 comprise a power signal line. Wherein, the first signal line X1 can be electrically connected to the power signal line.

In some embodiments, as shown in FIG. 9, the display panel comprises the first sub-edge 41 extending along the column direction y and the second sub-edge 42 extending along the row direction x. Wherein, the distance between the first connection electrode 31 adjacent to the first sub-edge 41 and the first sub-edge 41 is less than the distance between the transistors adjacent to the first sub-edge 41 and the first sub-edge 41, and the distance between the first connection electrode 31 adjacent to the second sub-edge 42 and the second sub-edge 42 is less than the distance between the transistors adjacent to the second sub-edge 42 and the second sub-edge 42. Such a configuration increases the distance between the transistors adjacent to the first sub-edge 41 and the first sub-edge 41, and at the same time increases the distance between the transistors adjacent to the second sub-edge 42 and the second sub-edge 42. It is possible to reduce the risk of failure of the transistors near the cutting edge when the first sub-edge 41 is formed by laser cutting, and also it is possible to reduce the risk of failure of the transistors near the cutting edge when the second sub-edge 42 is formed by laser cutting. It is possible to improve the yield of products with narrow bezels in both the row and column directions.

As shown in FIG. 9, the plurality of connection electrodes 30 comprise first electrodes 30a and second electrodes 30b, and one first electrode 30a and one second electrode 30b form an electrode group 30z. The pixel circuit 50 is coupled to the first electrode 30a. The plurality of connection electrodes 30 are provided along the row direction x to form electrode rows 30H. The electrode rows 30H comprise a plurality of first electrodes 30a and a plurality of second electrodes 30b. The electrode rows 30H comprise a first electrode row 30H1, which is adjacent to the second sub-edge 42. The display panel further comprises first common electrode lines 71 extending in the row direction x, and a plurality of second electrodes 30b in an electrode row 30H are electrically connected to one first common electrode line 71. Wherein, the first common electrode line 71 connected to the first electrode row 30H1 is located on a side of the first electrode row 30H1 away from the second sub-edge 42. One of the anode and cathode of a light-emitting device is bound to the first electrode 30a, and the other is bound to the second electrode 30b. The first electrode row 30H1 is used to bind a plurality of light-emitting devices adjacent to the second sub-edge 42. Therefore, the distance between the first electrode row 30H1 and the second sub-edge 42 affects the distance between the light-emitting devices at the edge positions and the second sub-edge 42. By providing the first common electrode line 71 connected to the first electrode row 30H1 at the side away from the second sub-edge 42, it is possible to reduce the distance between the first electrode row 30H1 and the second sub-edge 42, and in turn reduce the distance between the light-emitting devices and the second sub-edge 42, achieving a narrow-bezel or even bezel-free display panel.

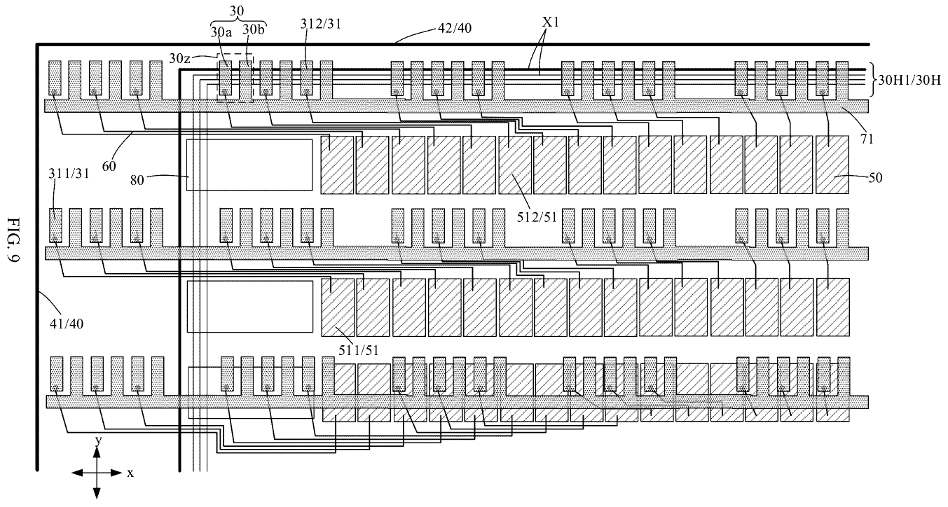

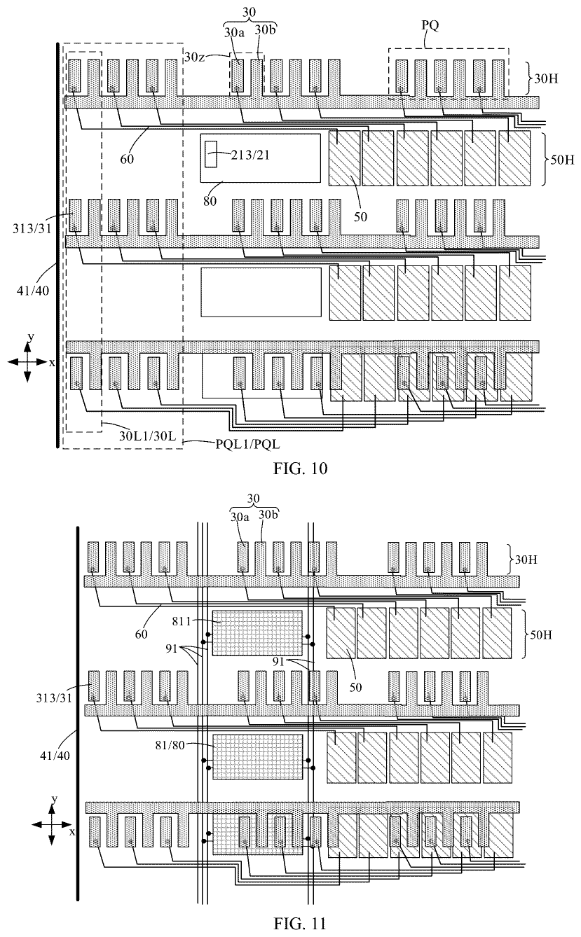

In other embodiments, the first transistor 21 is closest to the first edge 40 compared to other transistors. FIG. 10 is a schematic diagram of another display panel provided by an example of the present invention. As shown in FIG. 10, the first edge 40 comprises a first sub-edge 41 extending along the column direction y, the first transistor 21 comprises a third sub-transistor 213, and the first connection electrode 31 comprises a third connection sub-electrode 313. In the row direction x, the third sub-transistor 213 is adjacent to the first sub-edge 41, the third connection sub-electrode 313 is adjacent to the first sub-edge 41, and a distance between the third sub-transistor 213 and the first sub-edge 41 is greater than a distance between the third connection sub-electrode 313 and the first sub-edge 41. The column direction y and the row direction x are perpendicular to each other. The shift drive circuit 80 is located on a side of the plurality of pixel circuits 50 close to the first sub-edge 41. The shift drive circuit 80 comprises the third sub-transistor 213. The shift drive circuit 80 comprises a plurality of shift registers. The shift register can be any structure capable of implementing the signal shifting function in the prior art. The shift drive circuit 80 and the third sub-transistor 213 in FIG. 10 are both simplified for illustrative purposes. In the example in FIG. 10, the third sub-transistor 213 is adjacent to the first sub-edge 41 and belongs to the shift drive circuit 80. By providing the third sub-transistor 213 further away from the first sub-edge 41 compared to the third connection sub-electrode 313, it is possible to reduce the influence of the laser cutting process on the third sub-transistor 213 during the production of the display panel, thereby improving product yield.

Additionally, FIG. 10 also illustrates the electrode rows 30H and the pixel circuit rows 50H. The plurality of connection electrodes 30 are provided in the row direction x to form the electrode rows 30H, and the plurality of pixel circuits 50 are provided in the row direction x to form the pixel circuit rows 50H. In FIG. 10, a first pixel circuit row, a second pixel circuit row, and a third pixel circuit row are included from top to bottom in the column direction y. Wherein, both the first pixel circuit row and the second pixel circuit row are largely staggered from the electrode rows 30H in the column direction y, and the third pixel circuit row and the electrode row 30H connected thereto are substantially not staggered in the column direction y. The first pixel circuit row and the second pixel circuit row can be set as the inverted pixel circuit rows 50Hd described in the example in FIG. 8, and the third pixel circuit row is the regular pixel circuit row 50Hs. Such a configuration can reduce the wiring length of the bridging line 60 between the pixel circuit and the connection electrode 30.

As shown in FIG. 10, one first electrode 30a and one second electrode 30b form an electrode group 30z, and the pixel circuit 50 is coupled to the first electrode 30a. A plurality of electrode groups 30z are provided in the column direction y to form electrode columns 30L, and the electrode columns 30L comprise a first electrode column 30L1. The first electrode column 30L1 comprises the third connection sub-electrode 313. In the row direction x, the shift drive circuit 80 is located on a side of the first electrode column 30L away from the first sub-edge 41. Such a configuration can increase the distance between the shift drive circuit 80 and the first sub-edge 41, such that the distance between the third sub-transistor 213 in the shift drive circuit 80 and the first sub-edge 41 is increased, reducing the influence of the laser cutting process on the third sub-transistor 213, and improving product yield.

As shown in FIG. 10, three electrode groups 30z provided in the row direction x form a pixel region PQ, and in one pixel region PQ, a red light-emitting device, a green light-emitting device, and a blue light-emitting device are bound. The spacing between adjacent pixel regions PQ is greater than the spacing between the electrode groups 30z within a single pixel region PQ. A plurality of pixel regions PQ are provided in the column direction y to form pixel region columns PQL, and one pixel region column PQL comprises three electrode columns 30L. The pixel region columns PQL comprise a first pixel region column PQL1, which comprises the first electrode column 30L1. In the direction perpendicular to a plane of the substrate, the shift drive circuit 80 does not overlap the first pixel region column PQL1. In this embodiment, the shift drive circuit 80 and the first sub-edge 41 are spaced apart by at least the first pixel region column PQL1, such that the distance between the shift drive circuit 80 and the first sub-edge 41 is relatively great, ensuring that the third sub-transistor 213 in the shift drive circuit 80 has a sufficient safe distance from the first sub-edge 41, and the third sub-transistor 213 may not be damaged during the laser cutting process.

Three electrode groups 30z within a pixel region PQ are correspondingly connected to three pixel circuits 50 provided in the row direction x. In some embodiments of the present invention, the position of a pixel unit formed by three pixel circuits 50 provided in the row direction x is shifted in a direction away from the first sub-edge 41. In other words, the pixel circuits are shifted inward on a pixel unit basis.

In some embodiments, a part of the pixel units which are close to the first sub-edge 41 and the pixel regions PQ corresponding thereto are set to be staggered in the row direction x, and the spacing between the pixel circuits 50 in the part of the pixel units is less than the spacing between the pixel circuits in the regular pixel units. In this way, it is possible to increase the inward shift distance of the pixel circuits 50. Wherein, the regular pixel units are units composed of the pixel circuits in the pixel circuit array which are substantially not staggered from the electrode groups 30z. In some embodiments, the part of the pixel units which are close to the first sub-edge 41 and the pixel regions PQ corresponding thereto are set to be staggered in the row direction x, the part of the pixel units are referred to as shifted pixel units. The spacing between the pixel circuits 50 in the shifted pixel units is less than the spacing between the pixel circuits in the regular pixel units, and the spacing between the shifted pixel units is less than the spacing between the regular pixel units. A reduction in the spacing between the pixel circuits 50 in the shifted pixel units is different from a reduction in the spacing between the shifted pixel units. In some embodiments, the spacing between the pixel circuits 50 in the shifted pixel units is substantially the same as the spacing between the pixel circuits 50 in the regular pixel units, while the spacing between adjacent shifted pixel units is less than the spacing between adjacent regular pixel units. In other words, by compressing the spacing between adjacent pixel units, the distance between the shifted pixel units and the first sub-edge 41 is increased. The above embodiment can ensure that distances of the electrode groups 30z within one pixel region PQ form the pixel circuits 50 corresponding thereto remain essentially consistent, and the pixel circuits shifted to be inwardly retracted are better matched with the pixel region PQ, such that the driving performance are substantially consistent for the light-emitting devices within the pixel region PQ. Moreover, the above embodiment also facilitates the provision of the bridging lines between the inward shifted pixel circuits and the electrode groups 30z, simplifying the wiring in the display panel and saving space. In some embodiments, FIG. 11 is a schematic diagram of another display panel provided by an example of the present invention. As shown in FIG. 11, the shift drive circuit 80 comprises a first shift drive circuit 81, which is adjacent to the first sub-edge 41 and comprises the third sub-transistor (not indicated in FIG. 11). The first shift drive circuit 81 comprises a plurality of first shift registers 811 in cascade. The display panel further comprises a plurality of first drive signal lines 91, which are coupled to the first shift drive circuit 81. Wherein, at least one of the first drive signal lines 91 is located on a side of the first shift drive circuit 81 close to the first sub-edge 41. The first shift drive circuit 81 can be a scan drive circuit or a light emission drive circuit. The first drive signal lines 91 comprise at least a start signal line, two clock signal lines, and two power signal lines (a high-level signal line and a low-level signal line). In the example in FIG. 11, at least one of the first drive signal lines 91 is provided to be located at the side close to the first sub-edge 41, which can further increase the distance between the transistors in the first shift drive circuit 81 and the first sub-edge 41, making the transistors in the first shift drive circuit 81 safer during the laser cutting process.

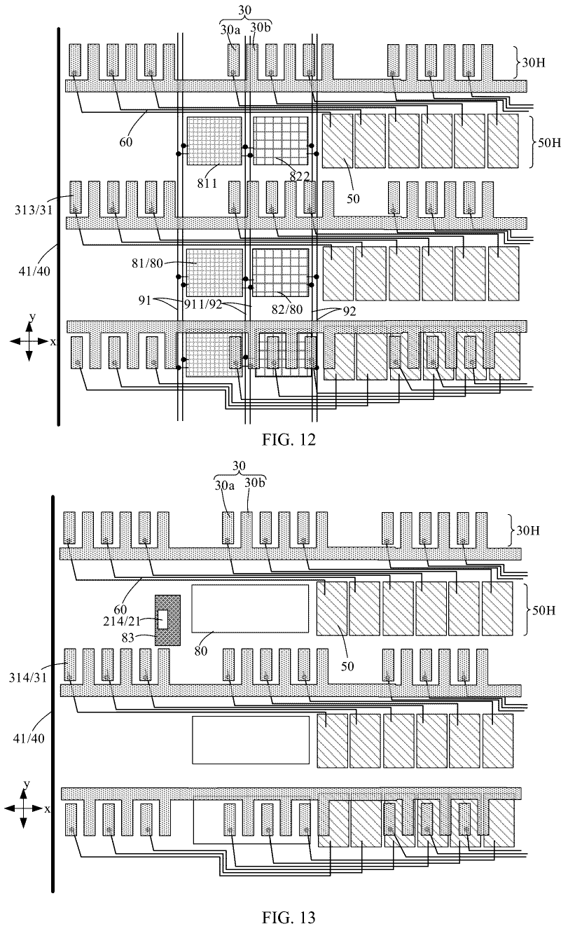

In some embodiments, FIG. 12 is a schematic diagram of another display panel provided by an example of the present invention. As shown in FIG. 12, the shift drive circuit 80 comprises a first shift drive circuit 81 and a second shift drive circuit 82, and the second shift drive circuit 82 is located on a side of the first shift drive circuit 81 away from the first sub-edge 41. The first shift drive circuit 81 comprises a plurality of first shift registers 811 in cascade, and the second shift drive circuit 82 comprises a plurality of second shift registers 822 in cascade. The display panel further comprises a plurality of second drive signal lines 92, which are coupled to the second shift drive circuit 82. The second drive signal lines 92 comprise at least a start signal line, two clock signal lines, and two power signal lines. The number of the first drive signal lines 91 and the number of the second drive signal lines 92 in FIG. 12 are only illustrative. Wherein, at least one of the second drive signal lines 92 is located on a side of the second shift drive circuit 82 that is away from the first sub-edge 41. Such a configuration makes it possible to maintain a certain distance between the shift drive circuit 80 and the pixel circuit 50, such that there is a certain spacing between the transistors of the two, thereby making it possible to provide some signal lines required for driving the pixel circuits.

Referring to the pixel circuit schematically shown in FIG. 2, in order to drive the pixel circuits, scan lines and light emission control lines are provided in the display panel. During driving of display, the pixel circuit rows are driven row by row, such that accordingly, a plurality of scan lines are provided with enable signals row by row, and also a plurality of light emission control lines are provided with enable signals row by row. The scan lines and the light emission control lines are connected to their corresponding shift drive circuits. One of the first shift drive circuit 81 and the second shift drive circuit 82 is a scan drive circuit, and the other is a light emission drive circuit. In one example, the first shift drive circuit 81 is a light emission drive circuit, and the second shift drive circuit 82 is a scan drive circuit, such that in the display panel, the scan lines are coupled to output terminals of the shift registers in the second shift drive circuit 82, and the light emission control lines are coupled to output terminals of the shift registers in the first shift drive circuit 81. FIG. 12 illustrates that both the scan drive circuit and light emission drive circuit are provided on one side of the pixel circuit array.

In other embodiments, the scan drive circuit and the light emission drive circuit are provided on two sides of the pixel circuit array, respectively. For example, the first shift drive circuit 81 illustrated in the example in FIG. 11 is one of the scan drive circuit and the light emission drive circuit, and the other shift drive circuit is provided on the other side of the pixel circuit array in the row direction x.

As shown in FIG. 12, the first drive signal lines 91 comprises at least one first drive signal sub-line 911. The first drive signal sub-line 911 is located between the first shift drive circuit 81 and the second shift drive circuit 82, and is reused as the second drive signal line 92. The second shift drive circuit 82 is coupled to the first drive signal sub-line 911. In this embodiment, the first shift drive circuit 81 and the second shift drive circuit 82 are provided to share at least one signal line, such as a power line, which can save space occupied by the shift drive circuit 80 and its drive signal lines in the row direction x. The distance between the shift drive circuit 80 and the first sub-edge 41 is increased, such that the transistors closest to the first sub-edge 41 in the shift drive circuit 80 cannot be affected by the laser cutting process. And increasing the distance between the shift drive circuit 80 and the first sub-edge 41 also affects the arrangement of the pixel circuits 50 in the row direction x. By saving space occupied by the shift drive circuit 80 and its drive signal lines in the row direction x, it is possible to reduce the staggered distance between the pixel circuit 50 and the connection electrode 30 at the edge position, shorten the length of the bridging line 60 between the pixel circuit 50 and the connection electrode 30, and reduce the voltage drop in the transmission of a signal through the bridging line 60.

In some embodiments, FIG. 13 is a schematic diagram of another display panel provided by an example of the present invention. As shown in FIG. 13, the first edge 40 comprises a first sub-edge 41 extending along the column direction y, the first transistor 21 comprises a fourth sub-transistor 214, and the first connection electrode 31 comprises a fourth connection sub-electrode 314. Along the row direction x, the fourth sub-transistor 214 is adjacent to the first sub-edge 41, the fourth connection sub-electrode 314 is adjacent to the first sub-edge 41, and a distance between the fourth sub-transistor 214 and the first sub-edge 41 is greater than a distance between the fourth connection sub-electrode 314 and the first sub-edge 41. The display panel further comprises a first ESD protection circuit 83, which comprises the fourth sub-transistor 214. FIG. 13 only schematically illustrates the first ESD protection circuit 83. The first ESD protection circuit 83 is used to release static electricity and prevent static electricity from damaging internal circuits. The specific structure of the first ESD protection circuit 83 is not limited in the example of the present invention. In this embodiment, the first ESD protection circuit 83 is the circuit structure closest to the first sub-edge 41 in the row direction x, that is, the first ESD protection circuit 83 is located on a side of the shift drive circuit 80 close to the first sub-edge 41. This embodiment can increase the distance between the fourth sub-transistor 214 and the first sub-edge 41, avoiding the damage to the fourth sub-transistor 214 caused by the laser cutting process during manufacturing, ensuring the integrity of the first ESD protection circuit 83, and in turn improving the performance reliability of the display panel.

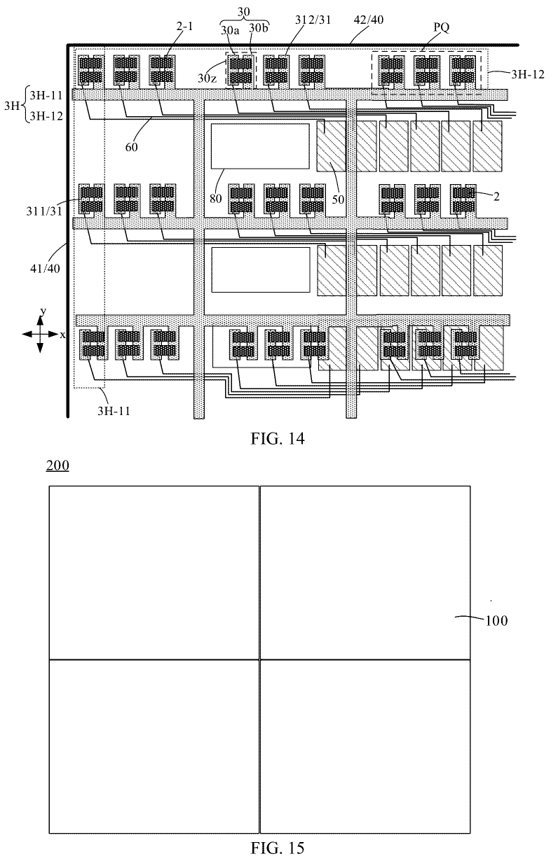

In some embodiments, FIG. 14 is a schematic diagram of another display panel provided by an example of the present invention. As shown in FIG. 14, the plurality of connection electrodes 30 are provided in an extension direction of the first edge 40 to form connection electrode rows 3H, which comprise an edge electrode row 3H-1 adjacent to the first edge 41, and the edge electrode row 3H-1 comprises the first connection electrode 31. The display panel comprises a plurality of light-emitting devices 2, which comprise first light-emitting devices 2-1. A plurality of first light-emitting devices 2-1 are bound and connected to the edge electrode row 3H-1, respectively. In the example of the present invention, the edge electrode row 3H-1 is the electrode row closest to the first edge 40 and correspondingly the first light-emitting devices 2-1 are bound and connected to the edge electrode row 3H-1, such that a light-emitting area of the display panel is closer to the first edge 40. Furthermore, due to the fact that in the example of the present invention, the transistors adjacent to the first edge 40 are further away from the first edge 40 compared to the first connection electrodes 31, ensuring the safety of the transistors when the first edge 40 is formed by laser cutting. At the same time, it is possible to have essentially no other lines between the first connection electrodes 31 and the first edge 40, achieving an extremely narrow bezel or even bezel-free display effect.

The plurality of connection electrodes 30 comprise first electrodes 30a and second electrodes 30b, and one first electrode 30a and one second electrode 30b form an electrode group 30z. The pixel circuit 50 is coupled to the first electrode 30a in the electrode group 30z. FIG. 14 schematically illustrates that one electrode group 30z is bound to two light-emitting devices 2. In other embodiments, one electrode group 30z is correspondingly bound to more than two light-emitting devices 2. Such a configuration can repair defective sub-pixels, ensuring normal light emission of the sub-pixels. Three electrode groups 30z sequentially provided in the row direction x form a pixel region PQ, and light-emitting devices 2 bound in a pixel region PQ comprise red light-emitting devices, blue light-emitting devices, and green light-emitting devices.

As shown in FIG. 14, the first edge 40 comprises a first sub-edge 41 and a second sub-edge 42. The edge electrode row 3H-1 comprises a first sub-edge electrode row 3H-11 adjacent to the first sub-edge 41 and a second sub-edge electrode row 3H-12 adjacent to the second sub-edge 42. The first sub-edge electrode row 3H-11 and the second sub-edge electrode row 3H-12 are each bound to a plurality of first light-emitting devices 2-1.

Referring to the example in FIG. 5, the first electrode row 30H1 in the example in FIG. 5 is the second sub-edge electrode row 3H-12, and the first electrode row 30H1 is bound to a plurality of light-emitting devices 2.

Referring to the example in FIG. 10, the first electrode column 30L1 in the example in FIG. 10 is the first sub-edge electrode row 3H-11, and the first electrode column 30L1 is bound to a plurality of light-emitting devices 2.

As shown in FIG. 7, in the scheme where the first edge 40 comprises the first sub-edge 41, a layout area of the plurality of connection electrodes 30 comprises a third region Q3 and a fourth region Q4. The third region Q3 is located on a side of the fourth region Q4 close to the first sub-edge 41, and the first connection electrode 31 is located in the third region Q3. Wherein, a layout density of the connection electrodes 30 within the third region Q3 is the same as a layout density of the connection electrodes 30 within the fourth region Q4.

As shown in FIG. 5, in the scheme where the first edge 40 comprises the second sub-edge 42, a layout area of the plurality of connection electrodes 30 comprises a third region Q3 and a fourth region Q4. The third region Q3 is located on a side of the fourth region Q4 close to the second sub-edge 42, and the first connection electrode 31 is located in the third region Q3. Wherein, a layout density of the connection electrodes 30 within the third region Q3 is the same as a layout density of the connection electrodes 30 within the fourth region Q4.

FIG. 5 and FIG. 7 also illustrate the first region Q1 and the second region Q2 divided based on different layout densities of the pixel circuits 50. In the examples of the present invention, a plurality of connection electrodes 30 are relatively evenly distributed in the display panel. By designing the layout pattern of the pixel circuits 50 and setting a part of the pixel circuits 50 to be staggered from the connection electrodes 30 connected thereto, the circuit adjacent to the first edge 40 is shifted in the direction away from the first edge 40, increasing the distance between the transistors at the edge position and the first edge 40, whereby being capable to ensure the safety of the transistors at the edge position in the process of forming the first edge 40 by the laser cutting process and improving product yield.

Based on the same inventive concept, an example of the present invention further provides a splicing screen. FIG. 15 is a schematic diagram of a splicing screen provided by an example of the present invention. As shown in FIG. 15, the splicing screen 200 comprises at least two display panels 100. The display panel 100 is a display panel provided by any example of the present invention. FIG. 15 illustrates that the splicing screen 200 comprises four display panels 100 in a 2*2 configuration. The structure of the display panel 100 has been described in the foregoing embodiments, and details are not repeated. The splicing screen 200 provided by the example of the present invention can be used for large-screen display, such as in conference rooms, exhibition halls, billboards, TV walls, and other occasions.

Based on the same inventive concept, an example of the present invention further provides a display apparatus comprising a display panel provided by any example of the present invention. In one example, the display apparatus comprises a single display panel. In another example, the display apparatus comprises a splicing screen formed by splicing at least two display panels.

The above description is merely for the preferred examples of the present invention, and is not intended to limit the present invention. Any modifications, equivalent replacements, improvements, and the like made within the spirit and principle of the present invention shall fall within the protection scope of the present invention.

Finally, it should be noted that the foregoing examples are merely intended to describe and not to limit the technical solutions of the present invention. Although the present invention has been described in detail with reference to the foregoing examples, those skilled in the art should understand that they can still make modifications to the technical solutions described in the foregoing examples or make equivalent replacements to some or all of the technical features thereof. These modifications or replacements do not make the essence of the corresponding technical solutions deviate from the scope of the technical solutions in the various examples of the present invention.

What is claimed is:

1. A display panel, comprising an array base plate, wherein the array base plate comprises a substrate as well as a plurality of transistors and a plurality of connection electrodes located on one side of the substrate;
wherein the plurality of transistors comprise a first transistor, the plurality of connection electrodes comprise a first connection electrode, and the array base plate has at least one first edge; and
the first transistor is adjacent to the first edge, the first connection electrode is adjacent to the first edge, and a distance between the first transistor and the first edge is greater than a distance between the first connection electrode and the first edge.

2. The display panel according to claim 1, wherein,
the array base plate comprises a plurality of pixel circuits located on the one side of the substrate, the pixel circuits comprise a first pixel circuit, and the first pixel circuit comprises the first transistor and is coupled to the first connection electrode.

3. The display panel according to claim 2, wherein,
the plurality of transistors further comprises a second transistor, and the plurality of connection electrodes further comprises a second connection electrode;
the pixel circuits further comprise a second pixel circuit, and the second pixel circuit comprises the second transistor and is coupled to the second connection electrode;
wherein a distance between the first transistor and the first connection electrode is greater than a distance between the second transistor and the second connection electrode.

4. The display panel according to claim 2, wherein,
the array base plate comprises a first bridging line, and the first pixel circuit is coupled to the first connection electrode through the first bridging line.

5. The display panel according to claim 4, wherein,
the array base plate comprises a first metal layer and a second metal layer, and the second metal layer is located on a side of the first metal layer away from the substrate; and
the first bridging line is located in the first metal layer, and the plurality of connection electrodes are located in the second metal layer.

6. The display panel according to claim 2, wherein,
a layout area of the pixel circuits comprises a first region and a second region, the first region is located on a side of the second region close to the first edge; and a layout density of the pixel circuits in the first region is greater than a layout density of the pixel circuits in the second region.

7. The display panel according to claim 2, wherein,
the array base plate comprises a shift drive circuit located on the one side of the substrate;
the first edge comprises a first sub-edge extending along a column direction, and the shift drive circuit is located on a side of the plurality of pixel circuits close to the first sub-edge;
the plurality of transistors further comprise a third transistor, and the shift drive circuit comprises the third transistor; and
along a row direction, a distance between the third transistor and the first sub-edge is greater than a distance between the first connection electrode and the first sub-edge, and the row direction is perpendicular to the column direction.

8. The display panel according to claim 2, wherein,
the first edge comprises a first sub-edge extending along a column direction, the first transistor comprises a first sub-transistor, and the first connection electrode comprises a first connection sub-electrode;
along a row direction, the first sub-transistor is adjacent to the first sub-edge, and the first connection sub-electrode is adjacent to the first sub-edge, a distance between the first sub-transistor and the first sub-edge being greater than a distance between the first connection sub-electrode and the first sub-edge; and the column direction is perpendicular to the row direction; and
the first pixel circuit comprises a first pixel sub-circuit, the first pixel sub-circuit comprises a first sub-transistor, and the first pixel sub-circuit is coupled to the first connection sub-electrode.

9. The display panel according to claim 8, wherein,
the plurality of connection electrodes comprise first electrodes and second electrodes; one of the first electrodes and one of the second electrodes form an electrode group; and the pixel circuit is coupled to the first electrode; and
a layout area of the pixel circuits comprises a first region, the pixel circuits in the first region and the electrode groups connected to the pixel circuits are staggered in the row direction, and the first pixel sub-circuit is located in the first region.

10. The display panel according to claim 2, wherein,
the first edge comprises a second sub-edge extending along a row direction, the first transistor comprises a second sub-transistor, and the first connection electrode comprises a second connection sub-electrode;
along a column direction, the second sub-transistor is adjacent to the second sub-edge, and the second connection sub-electrode is adjacent to the second sub-edge, a distance between the second sub-transistor and the second sub-edge being greater than a distance between the second connection sub-electrode and the second sub-edge, and the column direction is perpendicular to the row direction; and
the first pixel circuit comprises a second pixel sub-circuit, and the second pixel sub-circuit comprises the second sub-transistor and is coupled to the second connection sub-electrode.

11. The display panel according to claim 10, wherein,
the plurality of pixel circuits are provided along the row direction to form pixel circuit rows; the pixel circuit rows comprise a first pixel circuit row, and the first pixel circuit row comprises the second pixel sub-circuits;
the plurality of connection electrodes are provided along the row direction to form electrode rows; the electrode rows comprise a first electrode row, and the first electrode row comprises the second connection sub-electrodes; and
along the column direction, the first pixel circuit row is located on a side of the first electrode row away from the second sub-edge.

12. The display panel according to claim 11, wherein,
the electrode rows comprise a second electrode row located on a side of the first electrode row that is away from the second sub-edge, and the second electrode row is adjacent to the first electrode row; and
the first pixel circuit row is located between the first electrode row and the second electrode row.

13. The display panel according to claim 10, wherein,
the plurality of pixel circuits are provided along the row direction to form pixel circuit rows; the pixel circuit rows comprise a plurality of regular pixel circuit rows and at least one inverted pixel circuit row; a structure of the pixel circuits in the inverted pixel circuit row is symmetrical to a structure of the pixel circuits in the regular pixel circuit row with respect to a first axis, and the first axis extends along the row direction; and
the at least one inverted pixel circuit row comprises the second pixel sub-circuits.

14. The display panel according to claim 10, wherein,
the plurality of connection electrodes are provided along the row direction to form electrode rows; the electrode rows comprise a first electrode row, and the first electrode row comprises the second connection sub-electrodes;
the array base plate further comprises at least one first signal line extending along the row direction; and
in a direction perpendicular to a plane of the substrate, the first electrode row overlaps the first signal line.

15. The display panel according to claim 10, wherein,
the plurality of connection electrodes comprise first electrodes and second electrodes; one of the first electrodes and one of the second electrodes form an electrode group; and the pixel circuit is coupled to the first electrode;
the plurality of connection electrodes are provided along the row direction to form electrode rows; the electrode rows comprise a plurality of the first electrodes and a plurality of the second electrodes; the electrode rows comprise a first electrode row, and the first electrode row comprises the second connection sub-electrodes; and
the array base plate comprises first common electrode lines extending along the row direction, and the second electrodes in the electrode rows are connected to one of the first common electrode lines;
wherein the first common electrode lines connected to the first electrode row are located on a side of the first electrode row away from the second sub-edge.

16. The display panel according to claim 1, wherein,
the first edge comprises a first sub-edge extending along a column direction, the first transistor comprises a third sub-transistor, and the first connection electrode comprises a third connection sub-electrode;
along a row direction, the third sub-transistor is adjacent to the first sub-edge, and the third connection sub-electrode is adjacent to the first sub-edge, a distance between the third sub-transistor and the first sub-edge being greater than a distance between the third connection sub-electrode and the first sub-edge; and the column direction is perpendicular to the row direction;
the array base plate comprises a shift drive circuit and a plurality of pixel circuits located on the one side of the substrate, and the shift drive circuit is located on a side of the plurality of pixel circuits close to the first sub-edge; and
the shift drive circuit comprises the third sub-transistor.

17. The display panel according to claim 16, wherein,
the plurality of connection electrodes comprise first electrodes and second electrodes; one of the first electrodes and one of the second electrodes form an electrode group; the pixel circuit is coupled to the first electrode; a plurality of the electrode groups are provided along the column direction to form electrode columns, the electrode columns comprise a first electrode column, and the first electrode column comprises the third connection sub-electrodes; and
along the row direction, the shift drive circuit is located on a side of the first electrode column away from the first sub-edge.

18. The display panel according to claim 17, wherein,
three electrode groups provided along the row direction form one pixel region, a plurality of the pixel regions are provided along the column direction to form pixel region columns, and one pixel region column comprises three electrode columns; the pixel region columns comprise a first pixel region column, and the first pixel region column comprises the first electrode column; and
in a direction perpendicular to a plane of the substrate, the shift drive circuit does not overlap the first pixel region column.

19. The display panel according to claim 17, wherein,
the shift drive circuit comprises a first shift drive circuit, and the array base plate further comprises a plurality of first drive signal lines coupled to the first shift drive circuit;
wherein at least one of the first drive signal lines is located on a side of the first shift drive circuit away from the first sub-edge.

20. The display panel according to claim 19, wherein,
the shift drive circuit further comprises a second shift drive circuit located on a side of the first shift drive circuit away from the first sub-edge; and the array base plate further comprises a plurality of second drive signal lines coupled to the second shift drive circuit; and
wherein at least one of the second drive signal lines is located on a side of the second shift drive circuit away from the first sub-edge.

21. The display panel according to claim 20, wherein,
the first drive signal lines comprises at least one first drive signal sub-line located between the first shift drive circuit and the second shift drive circuit; and
the first drive signal sub-line is reused as the second drive signal line, and the second shift drive circuit is coupled to the first drive signal sub-line.

22. The display panel according to claim 1, wherein,
the first edge comprises a first sub-edge extending along a column direction, the first transistor comprises a fourth sub-transistor, and the first connection electrode comprises a fourth connection sub-electrode;
along a row direction, the fourth sub-transistor is adjacent to the first sub-edge, and the fourth connection sub-electrode is adjacent to the first sub-edge, a distance between the fourth sub-transistor and the first sub-edge being greater than a distance between the fourth connection sub-electrode and the first sub-edge; and the column direction is perpendicular to the row direction; and
the array base plate further comprises a first electrostatic discharge (ESD) protection circuit, and the first ESD protection circuit comprises the fourth sub-transistor.

23. The display panel according to claim 1, wherein,
the plurality of connection electrodes are provided along an extension direction of the first edge to form electrode rows; the electrode rows comprise an edge electrode row, and the edge electrode row is adjacent to the first edge and comprises the first connection electrodes;
the display panel comprises a plurality of light-emitting devices each comprising a first light-emitting device; and
a plurality of the first light-emitting devices are bound and connected to the edge electrode row.

24. The display panel according to claim 1, wherein,
a layout area of the plurality of connection electrodes comprises a third region and a fourth region, the third region is located on a side of the fourth region close to the first edge, and the first connection electrode is located in the third region; and
a layout density of the connection electrodes within the third region is the same as a layout density of the connection electrodes within the fourth region.

25. A splicing screen, comprising at least two display panels, wherein each of the display panels comprises a substrate as well as a plurality of transistors and a plurality of connection electrodes located on one side of the substrate;
wherein the plurality of transistors comprise a first transistor, the plurality of connection electrodes comprise a first connection electrode, and the array base plate has at least one first edge; and
the first transistor is adjacent to the first edge, the first connection electrode is adjacent to the first edge, and a distance between the first transistor and the first edge is greater than a distance between the first connection electrode and the first edge.

26. A display apparatus, comprising a display panel, wherein the display panel comprises a substrate as well as a plurality of transistors and a plurality of connection electrodes located on one side of the substrate;
wherein the plurality of transistors comprise a first transistor, the plurality of connection electrodes comprise a first connection electrode, and the array base plate has at least one first edge; and
the first transistor is adjacent to the first edge, the first connection electrode is adjacent to the first edge, and a distance between the first transistor and the first edge is greater than a distance between the first connection electrode and the first edge.
